(19) United States
(12) Patent Application Publication
(10) Pub. No.: US 2015/0279826 A1
(43) Pub. Date: Oct. 1, 2015

(54) OPTICAL MODULE WITH OPTICAL CONCENTRATION STRUCTURE AND PACKAGING METHOD THEREOF

(71) Applicant: Lingsen Precision Industries, Ltd., Taichung City (TW)

(72) Inventors: Ming-Te TU, Taichung City (TW); Chao-Wei YU, Taichung City (TW)

(21) Appl. No.: 14/306,875

(22) Filed: Jun. 17, 2014

(30) Foreign Application Priority Data
Mar. 31, 2014 (TW) 103112031

(51) Int. Cl. H01L 25/16; H01L 31/0203; H01L 33/48; H01L 33/52; H01L 31/0232; H01L 31/16; H01L 31/18

(52) U.S. Cl. CPC H01L 25/167; H01L 31/16; H01L 31/0203; H01L 31/18; H01L 33/52; H01L 25/165; H01L 31/02325; H01L 33/486; H01L 2933/005; H01L 2933/0058

(57) ABSTRACT

An optical module with optical concentration structure includes: a light-emitting chip and a light-receiving chip which are disposed at a light-emitting area and a light-receiving area of a substrate, respectively; a seal cap adapted to cover the substrate and including a first chamber for receiving the light-emitting chip, a second chamber for receiving the light-receiving chip, a light-emitting hole communicating with the first chamber, and a light-receiving hole communicating with the second chamber; a first encapsulant formed in the first chamber and the light-emitting hole, adapted to enclose the light-emitting chip, and having a first light-concentrating layer adjacent to the light-emitting hole; and a second encapsulant formed in the second chamber, adapted to enclose the light-receiving chip, and having a second light-concentrating layer adjacent to the light-receiving hole. The optical concentration structure enhances light emission efficiency of the optical module and reduces its packaging defect costs.

### BACKGROUND OF THE INVENTION

1. Technical Field

The present invention relates to optical modules, and more particularly, to an optical module with optical concentration structure.

2. Description of Related Art

A conventional proximity optical sensing module is presently a mainstream technological choice for a new-generation smart electronic device, such as a smartphone. As soon as the electronic device is put close to a user's ear (face detection) or put in the user's pocket, the module shuts down the display screen to save power and prevent any inadvertent touch, thereby enhancing user experience. The operation principle of the module is described as follows: a light-emitting chip, such as a light-emitting diode (LED), emits a light beam; the light beam reflects off the surface of an object and thus falls on a light-receiving chip; the light-receiving chip converts the light beam into an electronic signal for use in a subsequent process. For example, Taiwan patent M399313 discloses a proximity sensing package structure. The package structure comprises a base, a dam vertically connected to the periphery of the base, and a covering plate for covering the dam from above, wherein the base, the dam, and the covering plate together define a receiving space. The receiving space has therein a partition panel for partitioning the receiving space. Hence, the light-emitting chip and the light-receiving chip are mounted on a substrate and spaced apart from each other to thereby be insusceptible to interference from a light beam, thus preventing the deterioration of product performance.

However, Taiwan patent M399313 has a drawback, that is, as soon as a light beam emitted from the light-emitting chip are reflected off a light-concentrating reflecting layer and sent out from a bulging transparent plastic, the light beam is scattered without being focused and enhancing light emission efficiency. Taiwan patent M399313 has another drawback, that is, the covering plate and the dam are not integrally formed. As a result, a gap and even step-like mismatch is inevitably formed between the covering plate and the dam. If, in Taiwan patent M399313, the transparent plastic is disposed only at the dam, a portion of the scattered light beam irradiates the light-concentrating reflecting layer, another portion of the scattered light beam irradiates the gap, and yet another portion of the scattered light beam irradiates the step-like mismatch. As a result, all the portions of the reflected light beam are discrete and even interfere with each other.

In conclusion, the conventional optical module has the aforesaid drawbacks and thus still has room for improvement.

### SUMMARY OF THE INVENTION

It is an objective of the present invention to provide an optical module with optical concentration structure to not only enhance light emission efficiency but also greatly reduce the costs otherwise arising from bad packaging.

In order to achieve the above and other objectives, the present invention provides an optical module with optical concentration structure, comprising a substrate, a light-emitting chip, a light-receiving chip, a seal cap, a first encapsulant, and a second encapsulant. The substrate is defined with a light-emitting area and a light-receiving area. The light-emitting chip is disposed at the light-emitting area of the substrate. The light-receiving chip is disposed at the light-receiving area of the substrate. The seal cap is adapted to cover the substrate and includes a first chamber for receiving the light-emitting chip, a second chamber for receiving the light-receiving chip, a light-emitting hole communicating with the first chamber and being above the light-emitting chip, and a light-receiving hole communicating with the second chamber and being above the light-receiving chip. The first encapsulant, which is formed in the first chamber and the light-emitting hole, encloses the light-emitting chip and has a first light-concentrating layer adjacent to the light-emitting hole. The second encapsulant, which is formed in the second chamber, encloses the light-receiving chip and has a second light-concentrating layer adjacent to the light-receiving hole.

The outer surface of the first light-concentrating layer curves inward to form an inward-curving structure.

A surface of the second light-concentrating layer corresponds in position to the light-receiving hole and curves outward to form an outward-curving structure.

The seal cap comprises a top plate and a preshaped workpiece disposed between the top plate and the substrate. The top plate has the light-emitting hole and the light-receiving hole. The preshaped workpiece has the first and second chambers.

The preshaped workpiece has a first light-guiding layer formed on the lateral edge of the first chamber and expanding gradually in the outward direction.

The top plate has a second light-guiding layer formed on the lateral edge of the light-emitting hole and expanding gradually in the outward direction.

The present invention further provides a method of packaging an optical module with optical concentration structure. The method comprises the steps of:

forming a preshaped workpiece on a substrate;

defining a light-emitting area and a light-receiving area on the substrate;

connecting a light-emitting chip and a light-receiving chip electrically to the light-emitting area and the light-receiving area of the substrate, respectively;

fixing a top plate to the preshaped workpiece; and

filling the preshaped workpiece with a first encapsulant and a second encapsulant such that these encapsulants enclose the light-emitting chip and the light-receiving chip, respectively.

The method further comprises a step of forming the preshaped workpiece having a first chamber, a second chamber, and a first light-guiding layer by a die pressing process.

The method further comprises a step of forming the top plate having a light-emitting hole and a light-receiving hole by a die pressing process.

The method further comprises a step of forming a first light-concentrating layer of an inward-curving structure on a surface of the first encapsulant and a step of forming a second light-concentrating layer of an outward-curving structure on a surface of the second encapsulant.

Accordingly, the optical module with optical concentration structure of the present invention is characterized in that: light emission efficiency is enhanced by the light-concentrating layers of the encapsulants and the light-guiding layers at the first chamber and the light-emitting hole, respectively; and, before the chips get electrically connected to the substrate, the preshaped workpiece has been formed on the substrate such that, even if a defect is discovered during the subsequent packaging process of the seal cap, the die attach process of the chips can be dispensed with, thereby reducing the packaging defect costs greatly.

To help persons skilled in the art gain insight into the constituent elements, features, and objectives of the present invention, the present invention is hereunder illustrated with embodiments and drawings and described in detail so that persons skilled in the art can implement the present invention accordingly. However, the following description is merely illustrative of the implementation of the present invention in terms of technical solution and features. Hence, all simple modifications, replacements, and component reduction made to the aforesaid embodiments, without departing from the spirit of the present invention and by persons skilled in the art who have gained insight into the technical solution and features of the present invention, should fall within the scope of the intended protection for the present invention.

### BRIEF DESCRIPTION OF THE SEVERAL VIEWS OF THE DRAWINGS

Structures, features, and advantages of the present invention are hereunder illustrated with a specific embodiment in conjunction with the accompanying drawings, in which:

FIG. 1 is a top view of an optical module with optical concentration structure according to a preferred embodiment of the present invention;

FIG. 2 is a cross-sectional view of the optical module with optical concentration structure taken along line 2-2 of FIG. 1 according to the preferred embodiment of the present invention; and

FIG. 3 shows schematic views of the process flow of a method of packaging the optical module with optical concentration structure according to the preferred embodiment of the present invention.

### DETAILED DESCRIPTION OF THE EMBODIMENT OF THE INVENTION

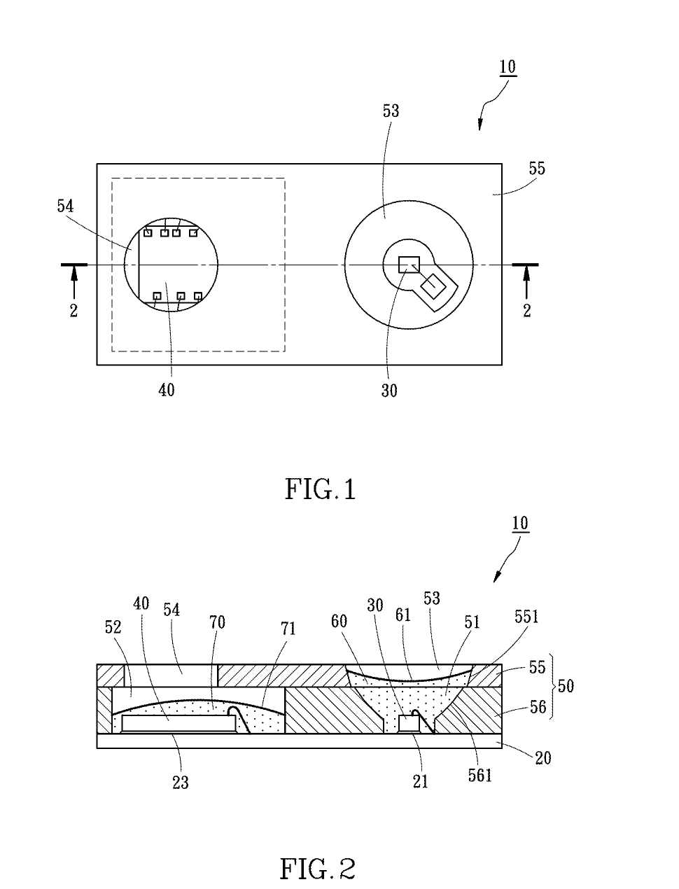

Referring to FIG. 1 and FIG. 2, in a preferred embodiment of the present invention, an optical module with optical concentration structure 10 comprises a substrate 20, a light-emitting chip 30, a light-receiving chip 40, a seal cap 50, a first encapsulant 60, and a second encapsulant 70.

The substrate 20 is made of an organic material and provided in the form of a non-ceramic substrate, such as a bismaleimide triazine substrate. The substrate 20 defines thereon a light-emitting area 21 and a light-receiving area 23.

The light-emitting chip 30 is disposed at the light-emitting area 21 of the substrate 20.

The light-receiving chip 40 is disposed at the light-receiving area 23 of the substrate 20.

The seal cap 50 covers the substrate 20 from above, includes a first chamber 51 and a second chamber 52, and has a light-emitting hole 53 in communication with the first chamber 51 and a light-receiving hole 54 in communication with the second chamber 52. The first chamber 51 receives the light-emitting chip 30, and the light-emitting hole 53 being above the light-emitting chip 30. The second chamber 52 receives the light-receiving chip 40, and the light-receiving hole 54 being above the light-receiving chip 40. In the preferred embodiment of the present invention, the seal cap 50 comprises a top plate 55 and a preshaped workpiece 56 disposed between the top plate 55 and the substrate 20. The light-emitting hole 53 and the light-receiving hole 54 are formed in the top plate 55. The first and second chambers 51, 52 are formed from the preshaped workpiece 56. Hence, the light-emitting chip 30 and the light-receiving chip 40 are separately disposed in the first chamber 51 and the second chamber 52, respectively, without interfering with each other.

The first encapsulant 60 is formed in the first chamber 51 and the light-emitting hole 53, encloses the light-emitting chip 30, and forms a first light-concentrating layer 61 adjacent to the light-emitting hole 53. The outer surface of the first light-concentrating layer 61 curves inward to form an inward-curving structure.

The second encapsulant 70 is formed in the second chamber 52, encloses the light-receiving chip 40, and forms a second light-concentrating layer 71 adjacent to the light-receiving hole 54. A surface of the second light-concentrating layer 71 corresponds in position to the light-receiving hole 54 and curves outward to form an outward-curving structure.

In the preferred embodiment of the present invention, the preshaped workpiece 56 has a first light-guiding layer 561 which is formed inwardly on the lateral edge of the first chamber 51 and expands gradually in the outward direction. Similarly, the top plate 55 has a second light-guiding layer 551 which is formed inwardly on the lateral edge of the light-emitting hole 53 and expands gradually in the outward direction. Hence, the light beam emitted from the light-emitting chip 30 is guided by the first light-guiding layer 561 and the second light-guiding layer 551 and focused in a specific direction, so as to enhance the light emission efficiency of the light-emitting chip 30. Furthermore, both the first encapsulant 60 and the second encapsulant 70 are a transparent silicon-based plastic. The outer surface of the first light-concentrating layer 61 of the first encapsulant 60 curves inward to form the inward-curving structure. A surface of the second light-concentrating layer 71 of the second encapsulant 70 corresponds in position to the light-receiving hole and curves outward to form the outward-curving structure. After the light beam emitted from the light-emitting chip 30 has been guided by the first and second light-guiding layers 561, 551 in passing the first light-concentrating layer 61 of the first encapsulant 60, the light beam gets focused once again because of the inward-curving structure. The light beam, which have hitherto been focused twice, falls on the surface of an object (not shown), reflects off the surface of the object, travels in the direction of the light-receiving chip 40, penetrates the light-receiving hole 54, reaches the second chamber 52, and is eventually focused on the light-receiving chip 40 by the outward-curving structure of the second light-concentrating layer 71, so as to enhance reception quality.

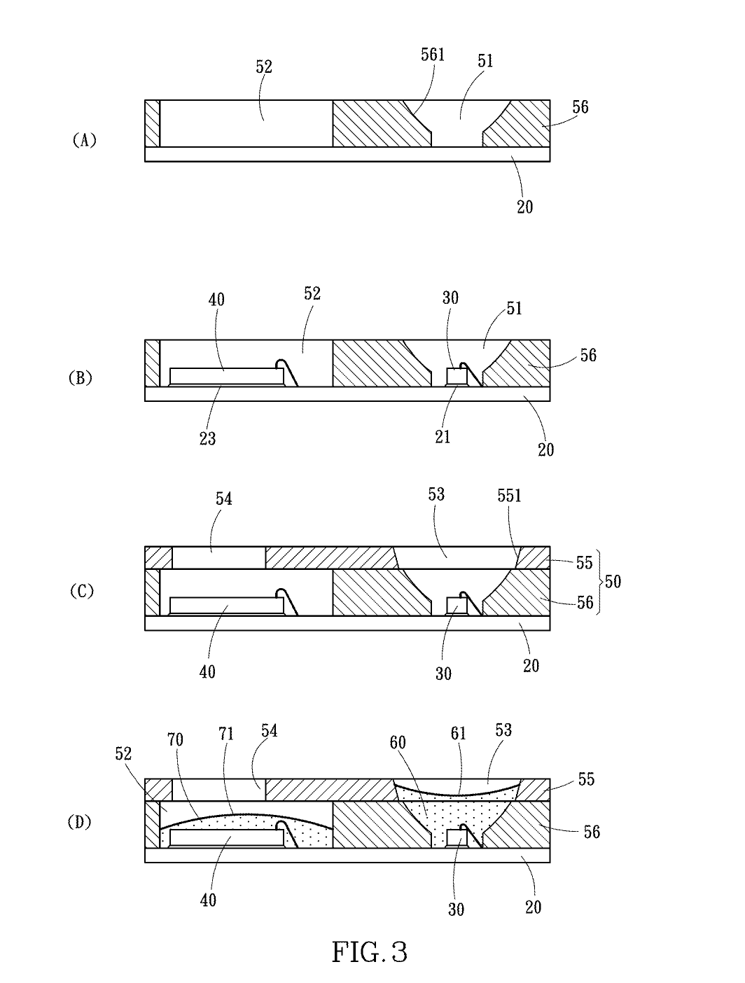

Referring to FIG. 3, the present invention provides a method of packaging an optical module with optical concentration structure 10. The method comprises the steps as follows:

Step A: forming the preshaped workpiece 56 on the substrate 20 in advance.

Step B: defining the light-emitting area 21 and the light-receiving area 23 on the substrate 20 and mounting the light-emitting chip 30 and the light-receiving chip 40 on the light-emitting area 21 and the light-receiving area 23 of the substrate 20 by a die attach process and a wire bonding process, respectively.

Step C: fixing the top plate 55 to the preshaped workpiece 56. In the preferred embodiment, step C involves aligning the top plate 55 with the preshaped workpiece 56 and then fixing the top plate 55 to the preshaped workpiece 56 by gluing.

Step D: filling the preshaped workpiece 56 with the encapsulants 60, 70 to cover the light-emitting chip 30 and the light-receiving chip 40 with the encapsulants 60, 70, respectively.

Prior to step A, feature structures, such as the first chamber 51, the second chamber 52, and the first light-guiding layer 561, are formed from the preshaped workpiece 56 by means of die pressing and then fixed to the substrate 20 by gluing, so as to dispense with any post-processing process which might otherwise have to be performed on the substrate 20. Moreover, as mentioned before, the light-receiving hole 54 and the light-emitting hole 53 having the second light-guiding layer 551 are formed at the top plate 55 by a die pressing process before step A.

In step D, the first chamber 51 and the second chamber 52 are filled with the first encapsulant 60 and the second encapsulant 70 in separate processes, respectively. Alternatively, in step D, the first and second chambers 51, 52 are filled with the first and second encapsulants 60, 70 in the same process, respectively. The choice between the aforesaid two alternatives depends on the requirements of a packaging process, such as reduction of labor costs, and reduction of defect costs. Moreover, the step D further involves forming on the surface of the first encapsulant 60 the inward-curving structure of the first light-concentrating layer 61 and forming on the surface of the second encapsulant 70 the outward-curving structure of the second light-concentrating layer 71, such that the path of the light beam is altered by the inward-curving structure and the outward-curving structure, so as to enhance light emission and reception efficiency.

In conclusion, the optical module with optical concentration structure 10 of the present invention is characterized in that: light emission efficiency is enhanced by the light-concentrating layers 61, 71 of the first and second encapsulants 60, 70 and the light-guiding layers 561, 551 at the first chamber 51 and the light-emitting hole 53, respectively; and, before the chips 30, 40 get electrically connected to the substrate 20, the preshaped workpiece 56 has been formed on the substrate 20 such that, even if a defect is discovered during the subsequent packaging process of the seal cap 50, the die attach process of the light-emitting chip 30 and the light-receiving chip 40 can be dispensed with, thereby reducing the packaging defect costs greatly.

Constituent elements disclosed in the above embodiments of the present invention are illustrative rather than restrictive of the scope of the present invention. Hence, all variations and replacements of equivalent components should fall within the claims of the present invention.

What is claimed is:

1. An optical module with optical concentration structure, comprising:
a substrate defined with a light-emitting area and a light-receiving area;
a light-emitting chip disposed at the light-emitting area of the substrate;
a light-receiving chip disposed at the light-receiving area of the substrate;
a seal cap adapted to cover the substrate and including a first chamber for receiving the light-emitting chip, a second chamber for receiving the light-receiving chip, a light-emitting hole communicating with the first chamber and being above the light-emitting chip, and a light-receiving hole communicating with the second chamber and being above the light-receiving chip;
a first encapsulant formed in the first chamber and the light-emitting hole, adapted to enclose the light-emitting chip, and having a first light-concentrating layer adjacent to the light-emitting hole; and
a second encapsulant formed in the second chamber, adapted to enclose the light-receiving chip, and having a second light-concentrating layer adjacent to the light-receiving hole.

2. The optical module with optical concentration structure of claim 1, wherein an outer surface of the first light-concentrating layer curves inward to form an inward-curving structure.

3. The optical module with optical concentration structure of claim 1, wherein a surface of the second light-concentrating layer corresponds in position to the light-receiving hole and curves outward to form an outward-curving structure.

4. The optical module with optical concentration structure of claim 1, wherein the seal cap comprises a top plate and a preshaped workpiece disposed between the top plate and the substrate, the top plate having the light-emitting hole and the light-receiving hole, and the preshaped workpiece having the first and second chambers.

5. The optical module with optical concentration structure of claim 4, wherein the preshaped workpiece has a first light-guiding layer formed on a lateral edge of the first chamber and expanding gradually in an outward direction.

6. The optical module with optical concentration structure of claim 4, wherein the top plate has a second light-guiding layer formed on a lateral edge of the light-emitting hole and expanding gradually in an outward direction.

7. A method of packaging an optical module with optical concentration structure, the method comprising the steps of:
forming a preshaped workpiece on a substrate;
defining a light-emitting area and a light-receiving area on the substrate;
connecting a light-emitting chip and a light-receiving chip electrically to the light-emitting area and the light-receiving area of the substrate, respectively;
fixing a top plate to the preshaped workpiece; and
filling the preshaped workpiece with a first encapsulant and a second encapsulant such that these encapsulants enclose the light-emitting chip and the light-receiving chip, respectively.

8. The method of claim 7, further comprising a step of forming the preshaped workpiece having a first chamber, a second chamber, and a first light-guiding layer by a die pressing process.

9. The method of claim 7, further comprising a step of forming the top plate having a light-emitting hole and a light-receiving hole by a die pressing process.

10. The method of claim 7, further comprising a step of forming a first light-concentrating layer of an inward-curving structure on a surface of the first encapsulant and a step of forming a second light-concentrating layer of an outward-curving structure on a surface of the second encapsulant.
